(19) United States
(12) Patent Application Publication
(10) Pub. No.: US 2024/0258938 A1
(43) Pub. Date: Aug. 1, 2024

(54) APPARATUS AND METHOD FOR DRIVING PIEZO ACTUATOR OF SMOOTH IMPACT DRIVE MECHANISM

(71) Applicant: CREPAS TECHNOLOGIES CO., LTD., Anyang-si (KR)

(72) Inventors: Sung Jun Joo, Seoul (KR); Chang Jun Oh, Daejeon (KR)

(21) Appl. No.: 18/415,500

(22) Filed: Jan. 17, 2024

(30) Foreign Application Priority Data
Jan. 19, 2023 (KR) 10-2023-0007716
Nov. 23, 2023 (KR) 10-2023-0164925

(51) Int. Cl. H02N 2/06

(52) U.S. Cl. CPC H02N 2/067

(57) ABSTRACT

The present disclosure relates to an SIDM piezo actuator driving apparatus and a method thereof, and the present disclosure provides an apparatus and a method for driving the SIDM piezo actuator capable of reducing heat generation and power consumption by removing the inrush current into the piezo actuator and capable of improving the vibration speed by increasing the applied voltage.

### CROSS-REFERENCE TO RELATED APPLICATION(S)

This application is based on and claims priority under 35 U.S.C. 119 to Korean Patent Application No. 10-2023-0007716, filed on Jan. 19, 2023, and Korean Patent Application No. 10-2023-0164925, filed on Nov. 23, 2023, in the Korean Intellectual Property Office, the disclosure of which is herein incorporated by reference in its entirety.

### BACKGROUND OF THE INVENTION

### 1. Field of the Invention

The present disclosure relates to an apparatus and a method for driving a piezo actuator and, in particular, to an apparatus and a method for driving a piezo actuator of a smooth impact drive mechanism (SIDM) capable of driving the piezo actuator in a smooth vibration manner.

### 2. Description of the Prior Art

FIG. 1 shows a conventional driving circuit 50 of a piezo actuator.

Referring to FIG. 1, the conventional piezo actuator driving circuit 50 is driven such that the equivalent capacitor of a piezo actuator Pz is charged through the main switches MT1 and MT4 between the power sources 10 and 20, such that when the resonance switches RT1 and RT2 are turned on, the voltage polarity of the capacitor changes through resonance of the resonance inductor L_{R} and the equivalent capacitor of the piezo actuator Pz, and such that when the main switches MT2 and MT3 on the other side are turned on, the amount of initial inrush current flowing into the equivalent capacitor of the piezo actuator Pz is reduced. At this time, theoretically, if the resistance in the resonance circuit RT1, RT2, and L_{R} is 0, the capacitor is charged with a voltage of the same magnitude and opposite polarity. At this time, the maximum voltage (V) applied to the capacitance (C) depending on the maximum current (i) of the inductance (L) of the resonance inductor L_{R} and the capacitance (C) of the capacitor is given by the following equation.

$$\frac{1}{2} {Li}^{2} = \frac{1}{2} {C V}^{2}$$

However, the internal resistance of the resonance circuit switches RT1 and RT2 and the internal resistance of the inductor L_{R} cause energy loss, and thus the voltage of opposite polarity applied to the capacitor during resonance becomes lower than the voltage of the power source 10 due to the above loss.

As the voltage of opposite polarity of the capacitor decreases, the inrush current into the capacitor increases when turning on the main switches MT1 and MT4/MT2 and MT3, and this increase in current leads to large power loss and EMI noise, so that the driving operation of the piezo actuator Pz deteriorates in many ways.

### SUMMARY OF THE INVENTION

Therefore, the present disclosure has been made to solve the above-mentioned problems, and the present disclosure provides an apparatus and a method for driving the SIDM piezo actuator capable of reducing heat generation and power consumption by removing the inrush current into the piezo actuator and capable of improving the vibration speed by increasing the applied voltage.

In addition, the present disclosure also provides an apparatus and a method for driving the SIDM piezo actuator capable of accurate displacement control by inserting an additional pulse for harmonics generation to apply a sawtooth wave (or triangle wave) that is advantageous for the piezo actuator driving.

A piezo actuator driving apparatus according to one aspect of the present disclosure may include: a first main switch and a second main switch connected in series between a first voltage and a second voltage, and having a contact point connected to one end of an inductor; a third main switch and a fourth main switch connected in series between the first voltage and the second voltage, and having a contact point connected to the other end of the inductor; and a first resonance switch, the piezo actuator, and a second resonance switch connected in series between one end and the other end of the inductor, wherein a resonance loop may be formed by connecting the piezo actuator and the inductor in a resonance period during which the first resonance switch and the second resonance switch are turned on, thereby providing energy pre-charged in the inductor to the piezo actuator.

A pre-loop may be formed by a parasitic diode in a direction of current flowing through the inductor, among a first parasitic diode of the first resonance switch made of a MOSEFET and a second parasitic diode of the second resonance switch made of a MOSEFET, and turning-on of the resonance switch on the other side before the resonance loop is formed in the resonance period between a forward drive and a reverse drive or between the reverse drive and the forward drive for the piezo actuator, thereby eliminating the discontinuity of the current flowing through the inductor at the moment of the resonance loop subsequent thereto.

A post-loop may be formed by a parasitic diode in a direction of current flowing through the inductor, among a first parasitic diode of the first resonance switch made of a MOSEFET and a second parasitic diode of the second resonance switch made of a MOSEFET, and turning-on of the resonance switch on the other side after the resonance loop formation period elapses between the forward drive and the reverse drive or between the reverse drive and the forward drive for the piezo actuator, thereby discharging residual current from the inductor to the piezo actuator, and thereafter, the first resonance switch and the second resonance switch may be driven to be turned off.

The piezo actuator may include a driving rod coupled to a piezo element and a slider into which the driving rod is inserted, and the positional displacement of the slider may be controlled through forward and backward movement according to the stick-slip drive of the slider by driving the piezo element according to a driving signal to vibrate the driving rod.

The first voltage may be a voltage at the output terminal of a forward diode connected to a source voltage.

A driving signal may be input as a square wave to both ends of the piezo actuator, and the forward or backward movement of the piezo actuator vibration may be determined according to the sum of high sections and the sum of low sections within one cycle of the driving frequency of the square wave, and an additional pulse for generating harmonics may be inserted at the midpoint of the low section within one cycle of the driving frequency.

According to another aspect of the present disclosure, a piezo actuator driving method for controlling the positional displacement of a slider into which a driving rod is inserted by driving a piezo element according to a driving signal to vibrate the driving rod coupled to the piezo element may include: inputting a driving signal for driving the piezo actuator as a square wave; determining the forward or backward movement of the piezo actuator vibration according to the sum of high sections and the sum of low sections within one cycle of the driving frequency of the square wave; and inserting an additional pulse for generating harmonics at the midpoint of the low section within one cycle of the driving frequency.

The width of the additional pulse may be determined such that the ratio of the sum of high sections to the sum of low sections within one cycle of the driving frequency of the square wave is determined in the range of 8.5:1.5 to 5.5:4.5.

In addition, according to another aspect of the present disclosure, a piezo actuator driving method of a driving apparatus that performs a forward drive in which a first voltage and a second voltage are respectively applied to a first electrode and a second electrode of a piezo actuator, and a reverse drive in which opposite voltages are respectively applied thereto, the driving apparatus including: a first main switch and a second main switch connected in series between the first voltage and the second voltage, and having a contact point connected to one end of an inductor; a third main switch and a fourth main switch connected in series between the first voltage and the second voltage, and having a contact point connected to the other end of the inductor; and a first resonance switch, the piezo actuator, and a second resonance switch connected in series between one end and the other end of the inductor, may include: (A) turning on the first main switch and the fourth main switch for the forward drive; (B) turning on the third main switch and the second main switch for the reverse drive; and (C) a resonance operation of turning on the first resonance switch and the second resonance switch between the forward drive and the reverse drive, wherein a resonance loop may be formed by connecting the piezo actuator and the inductor in the resonance operation, thereby providing energy pre-charged in the inductor to the piezo actuator.

According to the piezo actuator driving apparatus and method of the present disclosure, the inductor is charged with current, and when sufficient current is reached, the resonance switches are turned on to apply a voltage to the equivalent capacitor of the piezo actuator, so that the inductor is replenished with the current in proportion to the energy consumed in the resonance circuit in the subsequent operations, excluding the initial operation, thereby supplementing the insufficient voltage between both ends of the capacitor with the changed polarity.

Accordingly, 1) in terms of energy, in the prior art, in order to supplement the energy consumed when driving the resonance circuit to change the polarity of the equivalent capacitor of the piezo actuator, a voltage is applied to the capacitor to cause an inrush current, whereas, in the present disclosure, the inductor is supplemented with the current by the amount of energy consumed in the resonance circuit. In this case, even if a voltage is applied to both ends of the inductor, the current gradually increases from 0 due to the feature of the inductor's current, so there is an advantage in which a peak current does not flow like when a voltage source is applied directly to the capacitor. For example, it is possible to reduce heat generation and power consumption by eliminating the inrush current to the piezo actuator as described above, and for example, it will be possible, when driven at the same voltage, to reduce power consumption up to about 1/10 of the existing driving method and ⅓ of the existing eco-driving method.

2) In addition, since a higher voltage than the power source voltage can be applied to both ends of the equivalent capacitor of the piezo actuator by adjusting the magnitude of the current applied to the inductor, there is an advantage of obtaining the voltage input to the piezo actuator up to 2 to 3 times the power source voltage (e.g., power source voltage 3.3V->applied voltage 8V) without a separate DC-DC converter, thereby improving the vibration speed of the piezo actuator.

3) In addition, according to the present disclosure, accurate displacement control is possible by inserting an additional pulse for harmonics generation to apply a sawtooth wave (or triangle wave) that is advantageous for the piezo actuator driving.

### BRIEF DESCRIPTION OF THE DRAWINGS

The accompanying drawings, which are included as part of the detailed description to aid understanding of the present disclosure, provide embodiments of the present disclosure and explain the technical idea of the present disclosure along with the detailed description.

FIG. 1 illustrates a driving circuit of a conventional piezo actuator.

FIG. 2 illustrates an example of elements of a piezo actuator of the present disclosure.

FIG. 3 is a diagram illustrating a piezo actuator driving apparatus according to an embodiment of the present disclosure.

FIG. 4 is a timing diagram illustrating the operation of the driving apparatus in FIG. 3.

FIG. 5 is a reference diagram illustrating the forward drive and reverse drive states of the driving apparatus in FIG. 3.

FIG. 6 is a diagram illustrating a driving signal applied to a piezo actuator and displacement thereof according to the present disclosure.

FIG. 7 illustrates an example of a Bode diagram for the transfer function of a piezo actuator according to the present disclosure.

FIG. 8 is a diagram illustrating an additional pulse inserted into the driving signal for harmonics generation at the midpoint of the low section within one cycle of the driving frequency according to the present disclosure.

FIG. 9 illustrates an example of a signal waveform actually applied to a piezo actuator in the case where no additional pulse is inserted into a driving signal of the present disclosure.

FIG. 10 illustrates an example of a signal waveform actually applied to a piezo actuator in the case where an additional pulse is inserted into a driving signal of the present disclosure.

FIG. 11 illustrates a partial enlargement of the driving signal and piezo displacement thereof in the case where the additional pulse is not inserted in FIG. 9.

FIG. 12 illustrates a partial enlargement of the driving signal and piezo displacement thereof in the case where the additional pulse is inserted in FIG. 10.

### DETAILED DESCRIPTION OF THE EXEMPLARY EMBODIMENTS

Hereinafter, the present disclosure will be described in detail with reference to the attached drawings. Here, the same elements in respective drawings are indicated by the same reference numerals whenever possible. Additionally, detailed descriptions of already known functions and/or configurations will be omitted. The following description will be made based on the parts necessary to understand operations according to various embodiments, and descriptions of elements that may obscure the gist of the explanation will be omitted. In addition, some elements in the drawings may be exaggerated, omitted, or shown schematically. The sizes of the respective elements do not entirely reflect the actual sizes, and therefore the disclosure described here is not limited to the relative sizes or spacing of the elements drawn in the respective drawings.

In describing the embodiments of the present disclosure, if it is determined that a detailed description of the known technology related to the present disclosure may unnecessarily obscure the subject matter of the present disclosure, the detailed description will be omitted. In addition, the terms described below are defined in consideration of functions in the present disclosure, and may vary depending on the intention or custom of the user or operator. Therefore, the definition should be made based on the description throughout this specification. The terminology used in the detailed description is merely intended to describe embodiments of the present disclosure and must not be limited. Unless explicitly stated otherwise, singular expressions include plural expressions. In this description, expressions such as “include” or “have” are intended to indicate certain features, numbers, steps, operations, factors, or parts or combinations thereof, and they should not be construed to exclude the existence or possibility of one or more other features, numbers, steps, operations, factors, or parts or combinations thereof, other than those described above.

In addition, although terms such as “first”, “second”, etc. may be used to describe various elements, the elements are not limited to the terms, and the terms may be used only for the purpose of distinguishing one element from another element.

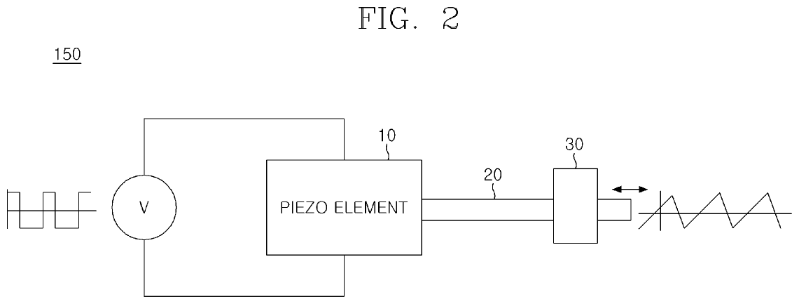

FIG. 2 illustrates an example of elements of a piezo actuator 150 of the present disclosure.

Referring to FIG. 2, the piezo actuator 150 of the present disclosure may include a piezo element 10, a driving rod 20 coupled to the piezo element 10, and a slider 30 into which the driving rod 20 is inserted. This piezo actuator 150 is a controllable element that vibrates the driving rod 20 by a PWM driving signal V to result in positional displacement of the slider 30, and is used in various fields for precision motion control such as focusing of camera modules, automobile fuel injection, and the like.

For example, when a PWM driving signal V is applied to the piezo element 10, the piezo element may vibrate the driving rod 20 in the forward or backward direction according to the driving signal V. At this time, the slider 30 coupled to the driving rod 20 inserted thereinto may slide. If the driving rod 20 is controlled to move slowly in the forward or backward direction, the driving rod 20 and the slider 30 are configured to move together as one unit (referred to as a “stick state”) because the friction force between the driving rod 20 and the slider 30 is greater than the inertial force of the slider 30. On the other hand, if the driving rod 20 is controlled to move faster than a threshold in the forward or backward direction, the driving rod 20 may slide while the slider 30 stays in its place (referred to as a “slip state”) because the friction force between the driving rod 20 and the slider 30 is less than the inertial force of the slider 30. In this way, the relatively positional displacement of the slider 30 may be controlled by appropriately controlling the vibration speed of the driving rod 20 in the forward or backward direction.

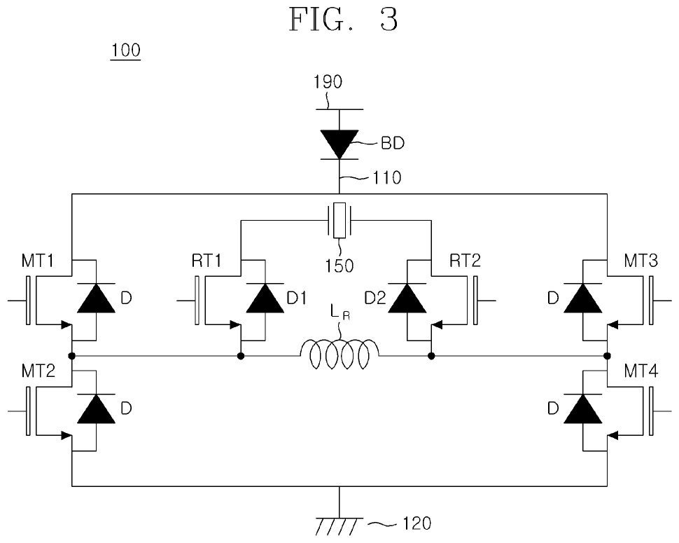

FIG. 3 is a diagram illustrating a piezo actuator driving apparatus 100 according to an embodiment of the present disclosure.

Referring to FIG. 3, the piezo actuator driving apparatus 100 according to an embodiment of the present disclosure includes a circuit to drive the piezo actuator 150, which includes a first main switch MT1, a second main switch MT2, a third main switch MT3, a fourth main switch MT4, a first resonance switch RT1, an inductor L_{R}, and a second resonance switch RT2. The piezo actuator driving apparatus may further include a forward diode BD connected between a source voltage 190 and a first voltage 110.

The switches, that is, the first main switch MT1, the second main switch MT2, the third main switch MT3, the fourth main switch MT4, the first resonance switch RT1, and the second resonance switch RT2, may be devices such as MOSFETs (Metal Oxide Silicon Field Effect Transistors) or IGBTs (Insulated Gate Transistors). In this case, as shown in the drawing, a parasitic diode D of each of the first main switch MT1, the second main switch MT2, the third main switch MT3, and the fourth main switch MT4, and respective parasitic diodes D1 and D2 of the first resonance switch RT1 and the second resonance switch RT2, which are formed during manufacturing, may be included.

In addition, the switches may be configured as BJT (Bipolar Junction Transistor) elements. In this case, the respective parasitic diodes D of the first main switch MT1, the second main switch MT2, the third main switch MT3, and the fourth main switch MT4 may be excluded, and the respective parasitic diode D1 and D2 of the first resonance switch RT1 and the second resonance switch RT2 may be excluded.

As will be described below, unless otherwise specified, the apparatus may be driven without the parasitic diodes D, D1, and D2 in the case where the switches are configured as BJT elements. Furthermore, unless otherwise specified, the switches may also be configured as a combination of IGBTs, MOSFETs, and BJTs.

However, even if the switches are configured as BJT elements, depending on the operation method of the resonance loop circuit RT1, RT2, L_{R}, and 150 including the piezo actuator 150 of the present disclosure, the diode (hereinafter referred to as a forward diode) D1 connected in parallel with the first resonance switch RT1 and the diode (hereinafter referred to as a reverse diode) D2 connected in parallel with the second resonance switch RT2 may be added, so the operation performed by employing the forward diode D1 and the reverse diode D2 will be described in the description of the corresponding operation.

As described above, depending on the device structure of the switches, the gate and drain/source terminals of the IGBT/MOSFET device may correspond to the base and emitter/collector (or collector/emitter) terminals of the BJT device.

As shown in FIG. 2, the piezo actuator 150 is a piezoelectric element that vibrates by the driving signal V applied to both electrodes, and is used in various fields for precision motion control such as focusing of camera modules, automobile fuel injection, and the like. The piezo actuator 150 may be interpreted as an electrically equivalent circuit including unique parasitic inductance (Lp) and charge capacity (Cp) determined by the mechanical structure, parasitic resistance (Rp) corresponding to the mechanical load, and parasitic stray capacitance (Cs) due to the influence of electrodes or surrounding conductors. For example, the resonance frequency is determined by the inductance (Lp) and the capacitance (C=Cp+Cs), and when the mechanical load is small, the resistance (Rp) decreases, and when the mechanical load is large, the resistance (Rp) increases.

Hereinafter, the forward drive (e.g., drive of vibration to the right in FIG. 2) is defined as the state in which a first voltage 110 (e.g., 3.3 volts) and a second voltage 120 (e.g., ground voltage) are applied to both electrodes of the piezo actuator 150, that is, a first electrode (e.g., the left electrode in FIG. 3) and a second electrode (e.g., the right electrode in FIG. 3), respectively. In addition, the reverse drive (e.g., drive of vibration to the left in FIG. 2) is defined as the state in which opposite voltages, that is the second voltage 120 (e.g., ground voltage) and the first voltage 110 (e.g., 3.3 volts), are applied to both electrodes of the piezo actuator 150, that is, the first electrode (e.g., the left electrode in FIG. 3) and the second electrode (e.g., the right electrode in FIG. 3), respectively.

As shown in FIG. 3, the first main switch MT1 and the second main switch MT2 are connected in series between the first voltage 110 and the second voltage 120, and the contact point thereof is connected to one end of the inductor L_{R}.

The third main switch MT3 and the fourth main switch MT4 are connected in series between the first voltage 110 and the second voltage 120, and the contact point thereof is connected to the other end of the inductor L_{R}.

The first resonance switch RT1, the piezo actuator 150, and the second resonance switch RT2 are connected in series between the first electrode and the second electrode of the piezo actuator 150.

As described above, the piezo actuator driving apparatus 100 may further include a forward diode BD connected between the source voltage 190 and the first voltage 110. In this case, the first voltage 110 is the voltage on the output terminal of the forward diode BD connected to the source voltage 190. The first voltage 110 and the source voltage 190 may be the same in the case of an ideal diode BD, but in reality, there may be a slight difference (e.g., 0.7 volts). If the voltage at any one end of the inductor L_{R} is greater than the first voltage 110, the diode BD may operate along with the parasitic diodes D1 and D2 such that the inductor L_{R} and the source voltage 190 are short-circuited, thereby preventing current from leaking.

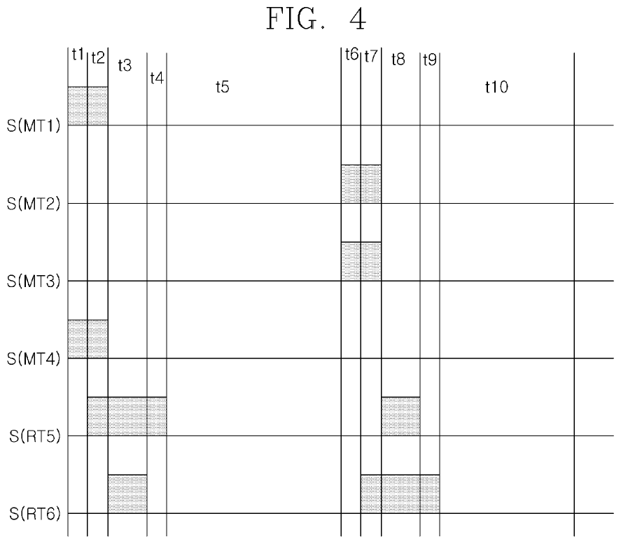

FIG. 4 is a timing diagram illustrating the operation of the driving apparatus 100 in FIG. 3.

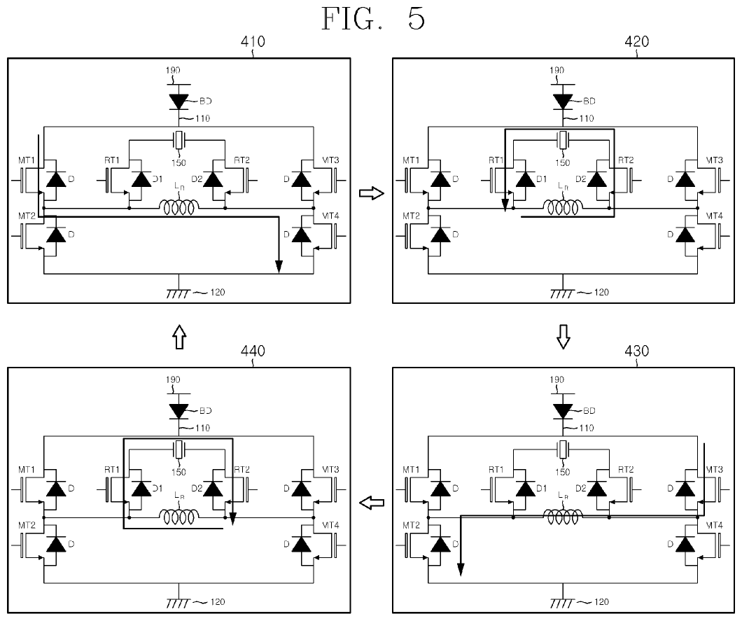

FIG. 5 is a reference diagram illustrating the forward drive and reverse drive states of the driving apparatus 100 in FIG. 3.

Referring to FIGS. 4 and 5, first, during periods t1 and t2 in FIG. 4, the first main switch MT1 and the fourth main switch MT4 may be turned on (MT3/MT2/RT1/RT2 turned off) by control signals S(MT1) and S(MT4) of a control device (not shown) applied as a logical high voltage to each gate terminal, as denoted by 410 in FIG. 5, thereby performing the forward drive (e.g., drive of vibration to the right in FIG. 2) of the piezo actuator 150.

In addition, during periods t6 and t7, the third main switch MT3 and the second main switch MT2 may be turned on (MT1/MT4/RT1/RT2 turned off) by control signals S(MT3) and S(MT2) of the control device applied as a logical high voltage to each gate terminal, as denoted by 430 in FIG. 5, thereby performing the reverse drive (e.g., drive of vibration to the left) of the piezo actuator 150.

In the present disclosure, during period t3 or t8 (resonance period) in FIG. 4 between the forward drive (MT1 and MT4 are turned on) and the reverse drive (MT3 and MT2 are turned on), the first resonance switch RT1 and the second resonance switch RT2 may be turned on, as denoted by 420 or 440 in FIG. 5, thereby performing resonance. This may be performed when the control signals S(RT1) and S(RT2) of the control device are applied, as a logical high voltage, to the respective gate terminals. That is, a resonance loop may be formed by connecting the piezo actuator 150 and the inductor L_{R} in the resonance period, thereby providing the energy previously charged in the inductor L_{R} to the piezo actuator for driving. In addition, since a higher voltage than the power source voltage 110 may be applied to both ends of the equivalent capacitor of the piezo actuator 150 by adjusting the magnitude of the current applied to the inductor L_{R} so that the voltage of the inductor L_{R} is applied to the piezo actuator 150 in the resonance period, there is an advantage of obtaining the voltage input to the piezo actuator 150 up to 2 to times the power source voltage (e.g., power source voltage 3.3V->applied voltage 8V) without a separate DC-DC converter, thereby improving the vibration speed of the piezo actuator 150.

In the present disclosure, the closed resonance loop in which resonance occurs in the resonance loop circuit RT1, RT2, L_{R}, and 150 may be formed in advance before the forward drive (MT1 and MT4 are turned on) and before the reverse drive (MT3 and MT2 are turned on) by configuring the resonance period to turn on the first resonance switch RT1 and the second resonance switch RT2 between the forward drive (MT1 and MT4 are turned on) and the reverse drive (MT3 and MT2 are turned on) or between the reverse drive (MT3 and MT2 are turned on) and the forward drive (MT1 and MT4 are turned on), thereby performing pre-charging such that the polarities of the capacitance at both ends of the piezo actuator 150 (see 430 and 440 in FIG. 5) conform to the corresponding driving direction.

That is, if the first resonance switch RT1 and the second resonance switch RT2 are turned on after the forward drive (MT1 and MT4 are turned on) and before the reverse drive (MT3 and MT2 are turned on), a resonance loop may be formed by the piezo actuator 150 and the inductor L_{R}, thereby performing pre-charging such that the polarities of the capacitance at both ends of the piezo actuator 150 conform to the reverse drive direction (e.g., −+) through the resonance (resonance cycle T=2π\sqrt{LC}) (e.g., ignoring the parasitic inductance (Lp)) occurring between the capacitance (C) of the piezo actuator 150 and the inductance (L) of the inductor L_{R}.

In addition, if the first resonance switch RT1 and the second resonance switch RT2 are turned on after the reverse drive (MT3 and MT2 are turned on) and before the forward drive (MT1 and MT4 are turned on), a resonance loop may be formed by the piezo actuator 150 and the inductor L_{R}, thereby performing pre-charging such that the polarities of the capacitance at both ends of the piezo actuator 150 conform to the forward drive direction (e.g., +−) through the resonance (resonance cycle T=2π\sqrt{LC}) occurring between the capacitance (C) of the piezo actuator 150 and the inductance (L) of the inductor L_{R}.

Furthermore, in the present disclosure, although the first resonance switch RT1 and the second resonance switch RT2 are turned off in the periods, excluding the resonance period after the forward drive (MT1 and MT4 are turned on) and the reverse drive (MT3 and MT2 are turned on), by providing the control signals S(RT1) and S(RT2) of the control device as a logical low voltage, any one of the first resonance switch RT1 and the second resonance switch RT2 may be turned on for a predetermined period of time in a pre-loop period before the resonance period and a pre-loop period after the resonance period.

That is, the first resonance switch RT1 may be turned on in advance in the pre-loop period t2 partially overlapping the forward drive (MT1 and MT4 are turned on) before the resonance period t3, and the second resonance switch RT2 may be turned off after the resonance period t3, but a post-loop period t4 may be included in which the first resonance switch RT1 remains turned on for a predetermined period of time.

In addition, in the reverse drive (MT3 and MT2 are turned on), the second resonance switch RT2 may be turned on in advance in the pre-loop period t7 partially overlapping the reverse drive (MT3 and MT2 are turned on) before the resonance period t8, and the first resonance switch RT1 may be turned off after the resonance period t8, but a post-loop period t9 may be included in which the second resonance switch RT2 remains turned on for a predetermined period of time.

More specifically, if the first resonance switch RT1 is turned on in advance in the pre-loop period t2, a pre-loop may be formed by the second parasitic diode D2 in the direction of current flowing through the inductor L_{R} and turning-on of the first resonance switch RT1 on the other side of the resonance circuit before the resonance loop is formed in the resonance period, thereby eliminating the discontinuity of the current flowing through the inductor L_{R} at the moment of the resonance loop subsequent thereto. That is, it may be driven to eliminate the discontinuity of the current flowing through the inductor L_{R} at the moment of resonance loop using the second parasitic diode D2 of the second resonance switch RT2, which is made of a device with a parasitic diode such as a MOSEFET or IGBT.

In addition, since the first resonance switch RT1 remains turned on for a predetermined period in the post-loop period t4, even after the resonance loop formation period elapses, a post-loop may be formed by the second parasitic diode D2 in the direction of current flowing through the inductor L_{R} and turning-on of the first resonance switch RT1 on the other side of the resonance circuit, thereby discharging residual current from the inductor L_{R} to the piezo actuator 150, and thereafter, the first resonance switch RT1 and the second resonance switch RT1 may be driven to be turned off. That is, discharging residual current from the inductor L_{R} to the piezo actuator 150 may be performed for a predetermined period of time after the resonance loop using the second parasitic diode D2 of the second resonance switch RT2, which is made of a device with a parasitic diode such as a MOSEFET or IGBT.

Likewise, if the second resonance switch RT2 is turned on in advance in the pre-loop period t7, a pre-loop may be formed by the first parasitic diode D1 in the direction of current flowing through the inductor L_{R} and turning-on of the second resonance switch RT2 on the other side of the resonance circuit before the resonance loop is formed in the resonance period, thereby eliminating the discontinuity of the current flowing through the inductor L_{R} at the moment of the resonance loop subsequent thereto. That is, it may be driven to eliminate the discontinuity of the current flowing through the inductor L_{R} at the moment of resonance loop using the first parasitic diode D1 of the first resonance switch RT1, which is made of a device with a parasitic diode such as a MOSEFET or IGBT.

In addition, similarly, since the second resonance switch RT2 remains turned on for a predetermined period in the post-loop period t9, even after the resonance loop formation period elapses, a post-loop may be formed by the first parasitic diode D1 in the direction of current flowing through the inductor L_{R} and turning-on of the second resonance switch RT2 on the other side of the resonance circuit, thereby discharging residual current from the inductor L_{R} to the piezo actuator 150, and thereafter, the first resonance switch RT1 and the second resonance switch RT1 may be driven to be turned off. That is, discharging residual current from the inductor L_{R} to the piezo actuator 150 may be performed for a predetermined period of time after the resonance loop using the first parasitic diode D1 of the first resonance switch RT1, which is made of a device with a parasitic diode such as a MOSEFET or IGBT.

Meanwhile, as described in FIG. 2, the piezo actuator 150 may include a driving rod 20 coupled to the piezo element 10 and a slider 30 into which the driving rod 20 is inserted, and the time-dependent positional displacement of the slider 30 may be controlled through forward and backward movement according to the stick-slip drive of the slider 30 by driving the piezo element 10 according to the driving signal V to vibrate the driving rod 20.

The driving signal V may be a signal applied to both ends of the piezo actuator 150 by control signals S(MT1), S(MT2), S(MT3), and S(MT4) of a control device (not shown). The driving signal may be input as a square wave to both ends of the piezo actuator 150, and the forward or backward movement of piezo actuator vibration may be determined according to the sum of high sections and the sum of low sections within one cycle of the driving frequency of the square wave. As described below, an additional pulse to generate harmonics may be inserted at the midpoint of the low section within one cycle of the driving frequency, thereby apply a sawtooth wave (or triangle wave) that is advantageous for driving the piezo actuator 150.

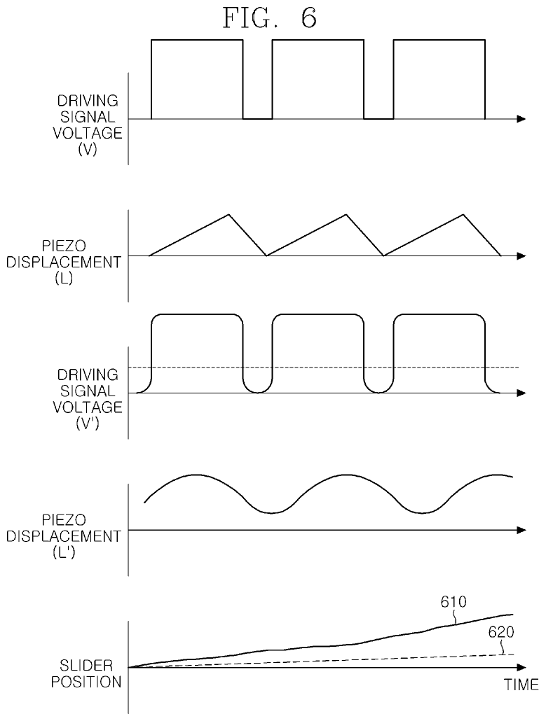

FIG. 6 is a diagram illustrating a driving signal V applied to a piezo actuator 150 and displacement thereof according to the present disclosure.

Referring to FIG. 6, for example, if a square wave PWM driving signal V is applied to the piezo element 10, the piezo element 10 may vibrate the driving rod 20 in the forward or backward direction by the driving signal V. At this time, the slider 30 coupled to the driving rod 20 inserted thereinto may slide. If the driving rod 20 is controlled to move slowly in the forward or backward direction, the driving rod 20 and the slider 30 are configured to move together as one unit (referred to as a “stick state”) because the friction force between the driving rod 20 and the slider 30 is greater than the inertial force of the slider 30. If the driving rod 20 is controlled to move faster than a threshold in the forward or backward direction, the driving rod 20 may slide while the slider 30 stays in its place (referred to as a “slip state”) because the friction force between the driving rod 20 and the slider 30 is less than the inertial force of the slider 30. In this way, the relatively positional displacement of the slider 30 may be controlled by appropriately controlling the vibration speed of the driving rod 20 in the forward or backward direction.

That is, the forward or backward vibration of the piezo actuator 150 may be determined depending on the sum of high sections and the sum of low sections within one cycle of the driving frequency of the square wave of the driving signal V. As shown in FIG. 6, the example shows the case where the ratio of the sum of high sections to the sum of low sections within one cycle of the driving frequency of the square wave of the driving signal V is 7:3. Here, as shown in the drawing, the driving rod 20 and the slider 30 may move forward at a slower speed due to the occurrence (small slope) of time-dependent displacement L of the piezo element 10, that is, the driving rod 20 in the high section of the square wave of the driving signal V, and the driving rod 20 may move backwards at a high speed due to the occurrence (large slope) of reverse displacement L of the piezo element 10, that is, the driving rod 20 in the low section of the square wave of the driving signal V, so that the positional displacement of the slider 30 may gradually increase in the forward direction (610). In order to obtain such a displacement of the slider 30, in addition to the case where the ratio of the sum of high sections to the sum of low sections within one cycle of the driving frequency of the square wave of the driving signal V is 7:3, the duty ratio thereof may be determined in the range of 8.5:1.5 to 5.5:4.5 (i.e., A:B, when A is a real number between 5.5 and 8.5, B=10−A). In particular, theoretically, if the ratio of the sum of high sections to the sum of low sections within one cycle of the driving frequency of the square wave is 5:5, the slider 30 may stay in its original position without displacement.

As described above, if the ratio of the sum of high sections to the sum of low sections within one cycle of the driving frequency of the square wave of the driving signal V is 7:3, forward displacement may be obtained, and if the ratio is 3:7, backward displacement may be obtained. Although a sawtooth wave of the driving signal V may be generated and applied to the piezo element 10, in this case, it requires a large voltage of tens of volts or more so that increased power and additional elements must be provided, so this method is not generally used.

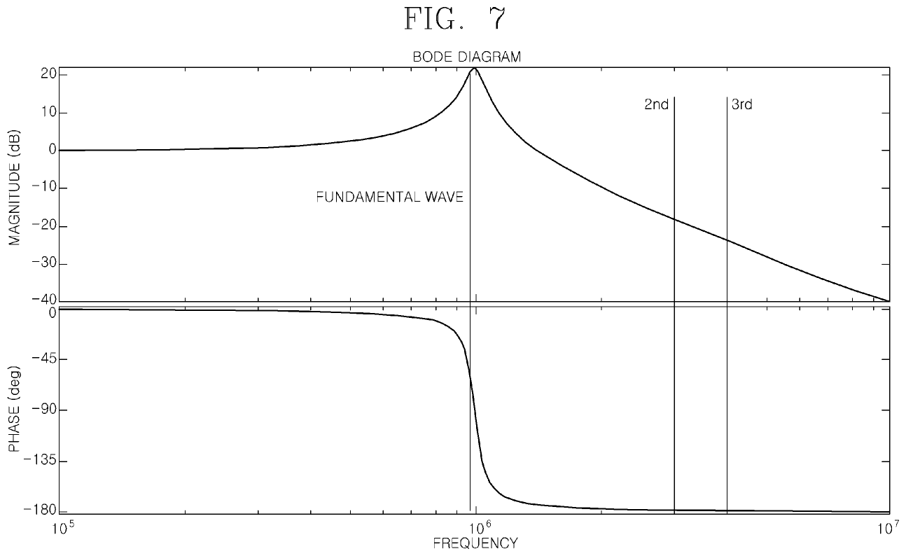

FIG. 7 illustrates an example of a Bode diagram for the transfer function of a piezo actuator 150 according to the present disclosure.

Referring to FIG. 7, as shown in the Bode diagram between the input and output when a square wave driving signal V is input to the piezo actuator 150, it provides a system in which the damping ratio is close to 0 as in the secondary system. At this time, if the frequency of the input waveform(e.g., 1 MHz) is appropriately selected and if a square wave with a duty ratio of 3:7 or 7:3 or similar is applied, the 4th or higher harmonics that interfere with the triangle wave may be attenuated by the second system filter, and the second and third harmonics dominantly appear relative thereto, thereby obtaining the time-dependent displacement L of the output terminal of the piezo actuator 150, that is, the piezo element 10 or driving rod 20, in the form of a triangle wave (see FIG. 6).

However, when adjusting the driving frequency, if the frequency is configured to be lower than the resonance frequency of the piezo actuator 150 in order to increase the second and third harmonics, the fundamental wave may be reduced, failing to obtain a large amplitude. On the other hand, if the frequency is increased close to the resonance frequency in order to obtain a large amplitude, the attenuation of the second and third harmonics becomes severe, making it impossible to obtain a desired time-dependent displacement of a triangular wave at the output terminal of the piezo actuator 150.

That is, as in the example of the driving signal V′ in FIG. 6, if a square wave with a gentle slope is applied as a driving signal due to an increase in attenuation of the second and third harmonics, that is, if a driving signal V′ with the reduced second and third harmonics is applied to the piezo actuator 150, a sinusoidal displacement L′, instead of a triangular wave, may be provided at the output terminal of the piezo actuator 150, that is, the piezo element 10 or driving rod 20, failing to obtaining the displacement of the slider 30 (see FIG. 6). At this time, a necessary displacement speed of the piezo element 10, that is, the driving rod 20, is not obtained, which makes it impossible to cause the forward or backward displacement of the slider 30 (610).

In other words, it can be seen that if the driving signal V of the square wave does not contain sufficiently large second and third harmonics, a satisfactory triangle wave cannot be obtained from the output terminal.

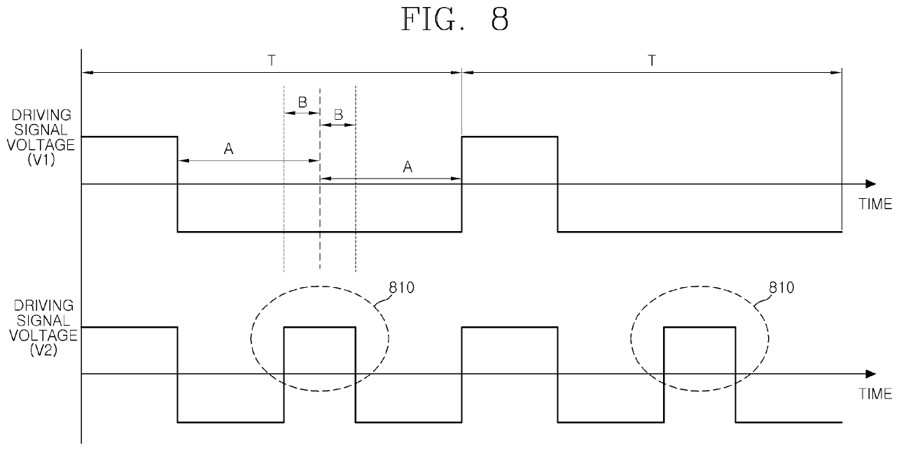

FIG. 8 is a diagram illustrating an additional pulse 810 inserted into the driving signal V1 for harmonics generation at the midpoint of the low section within one cycle of the driving frequency according to the present disclosure.

Referring to FIG. 8, in the case where the driving signal for driving the piezo actuator 150 is input as a square wave, the piezo actuator 150 may be driven using a driving signal V2 including an additional pulse 810 inserted for harmonics generation at the midpoint of the low section (center of 2A) within one cycle T of the driving frequency. The width (2B) of the additional pulse 810 may be determined and applied such that the half-width B thereof from the midpoint of the low section within one cycle T of the driving frequency is smaller than the half-width A of the low section within one cycle T (B<A).

Although FIG. 8 illustrates an example where the ratio of the sum of low sections to the sum of high sections within one cycle of the driving frequency of the square wave in the driving signal V1 without the additional pulse 810 is 3:7, the present disclosure it is not limited thereto, and the pulse width may be determined such that the ratio is in the range of 1.5:8.5 to 4.5:5.5.

In addition, even when the piezo actuator 150 is driven using a driving signal V2 including the additional pulse 810, the pulse width may be determined such that the ratio of the sum of high sections to the sum of low sections within one cycle of the driving frequency of the square wave including the additional pulse 810 is determined in the range of 8.5:1.5 to 5.5:4.5 (forward displacement occurs), and the pulse width may be determined such that the ratio of the sum of high sections to the sum of low sections within one cycle of the driving frequency of the square wave including the additional pulse 810 is determined in the range of 1.5:8.5 to 4.5:5.5 (backward displacement occurs).

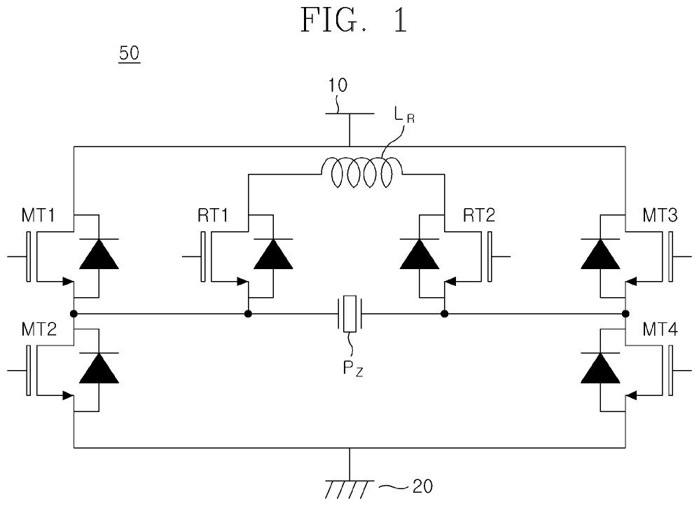

The driving method shown in FIG. 8 may be applied to conventional circuits in FIG. 1, as well as the circuit in FIG. 3, and may also be applied to various devices for driving the piezo actuator 150. That is, the method of driving the piezo element 10 using the driving signal V2 to generate the vibration of the driving rod 20 coupled to the piezo element 10 may be applied to all piezo actuator driving methods for controlling the positional displacement of the slider 30 through the forward and backward movement according to the stick-slip drive of the slider 30 into which the driving rod 20 is inserted.

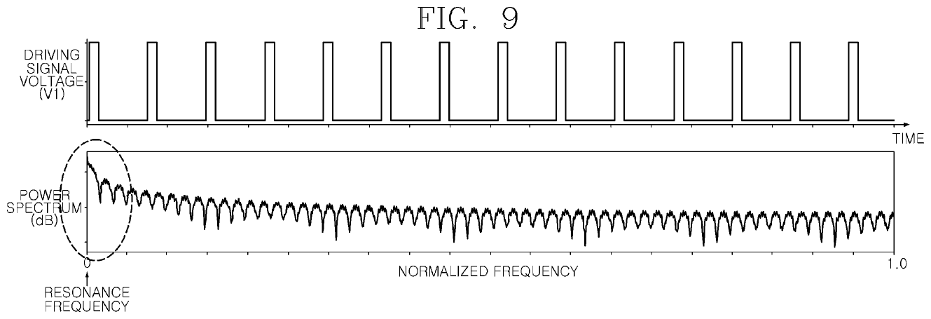

FIG. 9 illustrates an example of a signal waveform actually applied to a piezo actuator 150 in the case where no additional pulse is inserted into a driving signal V1 of the present disclosure.

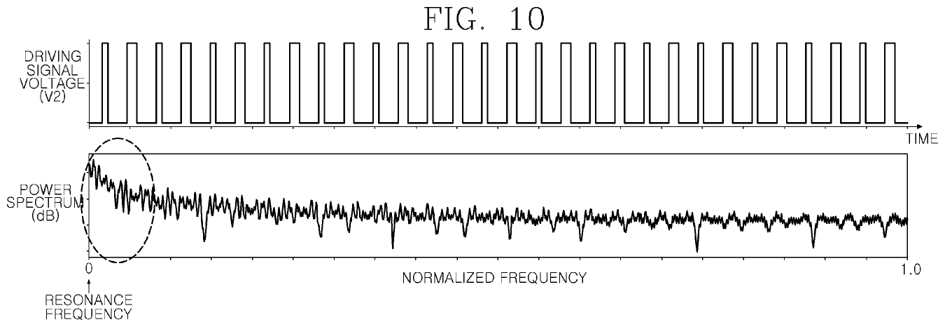

FIG. 10 illustrates an example of a signal waveform actually applied to a piezo actuator 150 in the case where an additional pulse is inserted into a driving signal V2 of the present disclosure.

Referring to FIGS. 9 and 10, it was confirmed that the driving signal V2, into which an additional pulse 810 is inserted, has a higher value of power spectrum (dB) than the driving signal V1, into which the additional pulse is not inserted, in the area of the second and third harmonics around the resonance frequency in the frequency analysis. This can be confirmed by passing through the second-order system with ζ(damping ratio)=0.02.

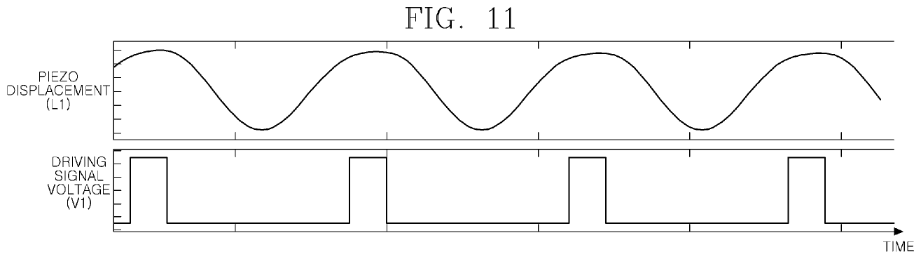

FIG. 11 illustrates a partial enlargement of the driving signal V1 and piezo displacement L1 thereof in the case where the additional pulse is not inserted in FIG. 9.

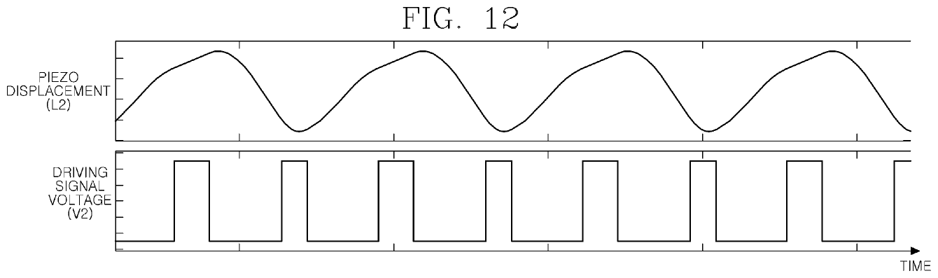

FIG. 12 illustrates a partial enlargement of the driving signal V2 and piezo displacement L2 thereof in the case where the additional pulse is inserted in FIG. 10.

Referring to FIGS. 11 and 12, compared to the driving signal V1 into which the additional pulse is not inserted, in the driving signal V2 into which the additional pulse 810 is inserted, the time-dependent displacement L2 of the output terminal of the piezo actuator 150, that is, the piezo element 10 or the driving rod 20, can be obtained in the form of a triangular wave, thereby enabling the displacement of the slider 30. In the driving signal V1 into which no additional pulse is inserted, a sinusoidal displacement L1 of the driving rod 20 may be obtained, which makes it impossible to control the displacement of the slider 30.

As described above, the driving method proposed in the present disclosure uses a method of further adding the additional pulse 810 to the midpoint corresponding to the half of the period having a longer duty in the existing driving waveform with a duty of 3:7 or similar, thereby greatly increasing the magnitude of the second and third harmonics. Accordingly, according to the driving method proposed in the present disclosure, even in SIDM driving using resonance, a sufficiently large ratio of triangle waves or sawtooth waves can be applied to the output terminal of the piezo actuator 150, that is, the piezo element or driving rod 20.

In other words, according to the piezo actuator driving apparatus 100 of the present disclosure, the inductor L_{R} is charged with current, and when sufficient current is reached, the resonance switches RT1 and RT2 are turned on to apply a voltage to the equivalent capacitor of the piezo actuator 150, so that the inductor L_{R} is replenished with the current in proportion to the energy consumed in the resonance circuit RT1, RT2, and L_{R} in the subsequent operations, excluding the initial operation, thereby supplementing the insufficient voltage between both ends of the capacitor with the changed polarity.

Accordingly, 1) in terms of energy, in the prior art, in order to supplement the energy consumed when driving the resonance circuit to change the polarity of the equivalent capacitor of the piezo actuator, a voltage is applied to the capacitor to cause an inrush current, whereas, in the present disclosure, the inductor L_{R} is supplemented with the current by the amount of energy consumed in the resonance circuit RT1, RT2, and L_{R}. In this case, even if a voltage is applied to both ends of the inductor L_{R}, the current gradually increases from 0 due to the feature of the current in the inductor L_{R}, so there is an advantage in which a peak current does not flow like when a voltage source is applied directly to the capacitor. For example, it is possible to reduce heat generation and power consumption by eliminating the inrush current to the piezo actuator 150 as described above, and for example, it will be possible, when driven at the same voltage, to reduce power consumption up to about 1/10 of the existing driving method and ⅓ of the existing eco-driving method.

2) In addition, since a higher voltage than the power source voltage can be applied to both ends of the equivalent capacitor of the piezo actuator 150 by adjusting the magnitude of the current applied to the inductor L_{R}, there is an advantage of obtaining the voltage input to the piezo actuator 150 up to 2 to 3 times the power source voltage (e.g., power source voltage 3.3V->applied voltage 8V) without a separate DC-DC converter, thereby improving the vibration speed of the piezo actuator 150.

3) In addition, according to the present disclosure, accurate displacement control is possible by inserting an additional pulse for harmonics generation to apply a sawtooth wave (or triangle wave) that is advantageous for driving of the piezo actuator 150.

As described above, although the present disclosure has been described with specific details, such as specific elements, limited embodiments, and drawings, this is only provided to facilitate the overall understanding of the present disclosure, and the present disclosure is not limited to the above embodiments, and those of ordinary skill in the art to which the present disclosure pertains will be able to make various modifications and variations without departing from the essential characteristics of the present disclosure. Therefore, the idea of the present disclosure should not be limited to the described embodiments, and the scope of the present disclosure should be construed to encompass, in addition to the claims described below, all technical ideas equivalent to the claims.

What is claimed is:

1. A piezo actuator driving apparatus comprising:
a first main switch and a second main switch connected in series between a first voltage and a second voltage, and having a contact point connected to one end of an inductor;
a third main switch and a fourth main switch connected in series between the first voltage and the second voltage, and having a contact point connected to the other end of the inductor; and
a first resonance switch, the piezo actuator, and a second resonance switch connected in series between one end and the other end of the inductor,
wherein a resonance loop is formed by connecting the piezo actuator and the inductor in a resonance period during which the first resonance switch and the second resonance switch are turned on, thereby providing energy pre-charged in the inductor to the piezo actuator.

2. The piezo actuator driving apparatus according to claim 1, wherein a pre-loop is formed by a parasitic diode in a direction of current flowing through the inductor, among a first parasitic diode of the first resonance switch made of a MOSEFET and a second parasitic diode of the second resonance switch made of a MOSEFET, and turning-on of the resonance switch on the other side before the resonance loop is formed in the resonance period between a forward drive and a reverse drive or between the reverse drive and the forward drive for the piezo actuator, thereby eliminating the discontinuity of the current flowing through the inductor at the moment of the resonance loop subsequent thereto.

3. The piezo actuator driving apparatus according to claim 1, wherein a post-loop is formed by a parasitic diode in a direction of current flowing through the inductor, among a first parasitic diode of the first resonance switch made of a MOSEFET and a second parasitic diode of the second resonance switch made of a MOSEFET, and turning-on of the resonance switch on the other side after the resonance loop formation period elapses between a forward drive and a reverse drive or between the reverse drive and the forward drive for the piezo actuator, thereby discharging residual current from the inductor to the piezo actuator, and thereafter, the first resonance switch and the second resonance switch are driven to be turned off.

4. The piezo actuator driving apparatus according to claim 1, wherein the piezo actuator comprises a driving rod coupled to a piezo element and a slider into which the driving rod is inserted, and wherein the positional displacement of the slider is controlled through forward and backward movement according to the stick-slip drive of the slider by driving the piezo element according to a driving signal to vibrate the driving rod.

5. The piezo actuator driving apparatus according to claim 1, wherein the first voltage is a voltage at the output terminal of a forward diode connected to a source voltage.

6. The piezo actuator driving apparatus according to claim 1, wherein a driving signal is input as a square wave to both ends of the piezo actuator,
wherein the forward or backward movement of the piezo actuator vibration is determined according to the sum of high sections and the sum of low sections within one cycle of the driving frequency of the square wave, and
wherein an additional pulse for generating harmonics is inserted at the midpoint of the low section within one cycle of the driving frequency.

7. A piezo actuator driving method for controlling the positional displacement of a slider into which a driving rod is inserted by driving a piezo element according to a driving signal to vibrate the driving rod coupled to the piezo element, the method comprising:
inputting a driving signal for driving the piezo actuator as a square wave;
determining the forward or backward movement of the piezo actuator vibration according to the sum of high sections and the sum of low sections within one cycle of the driving frequency of the square wave; and
inserting an additional pulse for generating harmonics at the midpoint of the low section within one cycle of the driving frequency.

8. The piezo actuator driving method according to claim 7, wherein the width of the additional pulse is determined such that the ratio of the sum of high sections to the sum of low sections within one cycle of the driving frequency of the square wave is determined in the range of 8.5:1.5 to 5.5:4.5.

9. A piezo actuator driving method of a driving apparatus that performs a forward drive in which a first voltage and a second voltage are respectively applied to a first electrode and a second electrode of a piezo actuator, and a reverse drive in which opposite voltages are respectively applied thereto,
the driving apparatus comprising:
a first main switch and a second main switch connected in series between the first voltage and the second voltage, and having a contact point connected to one end of an inductor;
a third main switch and a fourth main switch connected in series between the first voltage and the second voltage, and having a contact point connected to the other end of the inductor; and
a first resonance switch, the piezo actuator, and a second resonance switch connected in series between one end and the other end of the inductor, and
the method comprising:
(A) turning on the first main switch and the fourth main switch for the forward drive;
(B) turning on the third main switch and the second main switch for the reverse drive; and
(C) as a resonance operation, turning on the first resonance switch and the second resonance switch between the forward drive and the reverse drive,
wherein a resonance loop is formed by connecting the piezo actuator and the inductor in the resonance operation, thereby providing energy pre-charged in the inductor to the piezo actuator.
